(19) United States
(12) Patent Application Publication
(10) Pub. No.: US 2025/0083513 A1
(43) Pub. Date: Mar. 13, 2025

(54) ELECTRIC VEHICLE DRIVING DEVICE

(71) Applicant: Mitsubishi Electric Corporation, Tokyo (JP)

(72) Inventor: Shigetoshi Ipposhi, Tokyo (JP)

(73) Assignee: Mitsubishi Electric Corporation, Tokyo (JP)

(21) Appl. No.: 18/588,792

(22) Filed: Feb. 27, 2024

(30) Foreign Application Priority Data
Sep. 12, 2023 (JP) 2023-147313

(51) Int. Cl. B60K 11/02; B60K 6/445; H05K 7/20

(52) U.S. Cl. CPC B60K 11/02; B60K 6/445; H05K 7/209; H05K 7/20927

(57) ABSTRACT

This electric vehicle driving device includes: a motor; a gear box storing a speed reduction mechanism connected to the motor, and a differential mechanism connected to the speed reduction mechanism; an inverter which is electrically connected to the motor and converts power; and an oil cooler which oil-cools the motor. The inverter has first and second cooling water paths through which cooling water flows. The oil cooler has an oil-cooler water path through which the cooling water flows. The oil cooler is provided in contact with the inverter. At the contact part, the first cooling water path and the oil-cooler water path are connected, and the second cooling water path and the oil-cooler water path are connected. A water path is formed such that the cooling water flows in order of the first cooling water path, the oil-cooler water path, and then the second cooling water path.

### BACKGROUND

The present disclosure relates to an electric vehicle driving device.

In recent years, vehicles in which an internal combustion engine driven by being supplied with fuel from a fuel tank is used as motive power are being rapidly replaced with electric vehicles in which a motor driven by being supplied with electricity from a battery is used as motive power. In addition, on-vehicle devices for traveling of an electric vehicle have been arranged in an increasingly concentrated manner. Many of electric vehicle driving devices for traveling of an electric vehicle are configured such that mainly a motor for producing motive power, a speed reducer for transmitting, to a vehicle shaft, motive power with the speed of the motor reduced, and an inverter for converting DC current stored in a battery to desired AC current to efficiently perform drive control of the motor, are integrated. In each of the motor, the speed reducer, and the inverter, loss is generated through energy conversion or motive power transmission. Heat generation caused by the loss increases a local temperature of each device. Excessive increase in the local temperature of each device can cause failure of the electric vehicle driving device. Therefore, it is necessary to appropriately cool the electric vehicle driving device.

A general cooling structure for cooling the electric vehicle driving device is formed of an oil-cooled system which circulates oil in the electric vehicle driving device and an external-water-cooled system which supplies cooling water from the outside to an oil cooler which is a part of the oil-cooled system (for example, Patent Document 1). In the oil-cooled system, oil accumulated at a lower part in a housing storing a speed reducer is supplied through the oil cooler and one or a plurality of oil passages to a heat generation portion by an oil pump. By the oil contacting with the heat generation portion directly or indirectly, the oil absorbs heat, so that the heat generation portion is cooled, and the temperature-increased oil circulates back to the lower part in the housing again. The external-water-cooled system is formed by connecting a radiator, a cooling water pump, a water-cooled plate of an inverter, and the oil cooler by a pipe. The cooling water in the external-water-cooled system circulates by driving of the cooling water pump.

With this configuration, the cooling water is supplied from the external-water-cooled system to the oil cooler, and the high-temperature oil circulating in the oil-cooled system undergoes heat exchange with the cooling water at the oil cooler, whereby lowered-temperature oil can be supplied to the heat generation portion. Meanwhile, in the external-water-cooled system, the cooling water absorbs heat from the high-temperature oil at the oil cooler, and the temperature-increased cooling water dissipates heat at the radiator to the surrounding air. Low-temperature cooling water sent out from the radiator is supplied to the oil cooler again. In oil circulation in the oil-cooled system and cooling water circulation in the external-water-cooled system, heat is transferred from the heat generation portion of the electric vehicle driving device to the radiator via the oil and the cooling water, and the heat is released from the radiator to the surrounding air.

A specific configuration of a part where an oil cooler is provided in an electric vehicle driving device is disclosed (for example, Patent Document 2). In the disclosed configuration of the electric vehicle driving device, for enabling efficient heat exchange, an oil cooler having a rectangular parallelepiped shape and having an oil path and a cooling water path overlapped alternately is provided obliquely upward of a motor. At a contact surface between the motor and the oil cooler, two oil path connection portions are provided. Two L-shaped nipples are attached at the opposite surface of the oil cooler, and a hose through which cooling water passes is connected to the nipples, thus forming a pipe through which the cooling water flows. With this configuration, the cooling water can be passed through the pipe formed by the hose, and oil can be supplied from the oil path connection portion by an oil pump provided separately, whereby it is possible to efficiently perform heat exchange between the oil and the cooling water via a solid wall, in the oil cooler, which separates the oil path and the cooling water path from each other. Through heat exchange, low-temperature oil is sent out from the oil path connection portion of the oil cooler, and the low-temperature oil is supplied to a heat generation portion of the electric vehicle driving device, whereby the heat generation portion can be cooled.

Another specific configuration of a part where an oil cooler is provided in an electric vehicle driving device is disclosed (for example, Patent Document 3). In the disclosed configuration of the electric vehicle driving device, an oil cooler is stored in a gear box storing a speed reduction mechanism and a differential mechanism. With this configuration, there is no protrusion of the oil cooler itself in the electric vehicle driving device, so that the size of the electric vehicle driving device can be reduced. In addition, the electric vehicle driving device can be easily mounted into an electric vehicle.
Patent Document 1: Japanese Patent No. 7140727
Patent Document 2: Japanese Patent No. 7278845
Patent Document 3: Japanese Laid-Open Patent Publication No. 2000-295818

In Patent Document 2, heat exchange between oil and cooling water can be efficiently performed in the oil cooler, and the heat generation portion of the electric vehicle driving device can be cooled by low-temperature oil sent out from the oil path connection portion of the oil cooler. However, in the electric vehicle driving device, the oil cooler is attached in a protruding form, and further, the nipples for the cooling water protrude, so that a space for routing the hose as the pipe is needed around the nipples. Therefore, the volume efficiency of the electric vehicle driving device is very low, thus having a problem that the size of the electric vehicle driving device increases. In addition, there is a problem that the electric vehicle driving device cannot be easily mounted into the electric vehicle.

In Patent Document 3, since the oil cooler is stored in the gear box, the size of the electric vehicle driving device is reduced, and the electric vehicle driving device can be easily mounted into the electric vehicle. However, while there is no protruding part of the oil cooler itself, nipples for cooling water protrude around the oil cooler and a space for routing a hose as a pipe is needed around the oil cooler. Therefore, the volume efficiency of the electric vehicle driving device is low, thus having a problem that the size of the electric vehicle driving device increases. In addition, while the inside of the gear box needs to have a waterproof structure so that constituent members will not be rusted, a cooling water path in Patent Document 3 is stored in the gear box, and therefore there is a problem that the cooling water enters the inside of the gear box which is a waterproof region of the electric vehicle driving device. When the cooling water enters the inside of the gear box, the inside of the gear box might be rusted. In addition, since the gear box does not have a function of drainage from the inside of the gear box to the outside, there is a possibility that the cooling water also enters the inside of the motor. When the cooling water enters the inside of the motor, the cooling water can cause dielectric breakdown of a wire connection part in the motor, a coil of a stator, and the like, and this might lead to greater failure in the electric vehicle driving device.

### SUMMARY

Accordingly, an object of the present disclosure is to provide an electric vehicle driving device that does not need a pipe around an oil cooler and thus has a reduced weight and a reduced size, and that prevents entry of cooling water into a waterproof region and can be easily mounted into an electric vehicle.

An electric vehicle driving device according to the present disclosure includes: a motor; a gear box storing a speed reduction mechanism connected to the motor, and a differential mechanism connected to the speed reduction mechanism; an inverter which is electrically connected to the motor and converts power; and an oil cooler which oil-cools the motor. The inverter has a first cooling water path and a second cooling water path through which cooling water flows. The oil cooler has an oil-cooler water path through which the cooling water flows. The oil cooler is provided in contact with the inverter. At the contact part, the first cooling water path and the oil-cooler water path are connected, and the second cooling water path and the oil-cooler water path are connected. A water path is formed such that the cooling water flows in order of the first cooling water path, the oil-cooler water path, and then the second cooling water path.

In the electric vehicle driving device according to the present disclosure, the inverter has the first cooling water path and the second cooling water path through which the cooling water flows. The oil cooler has the oil-cooler water path through which the cooling water flows. The oil cooler is provided in contact with the inverter. At the contact part, the first cooling water path and the oil-cooler water path are connected, and the second cooling water path and the oil-cooler water path are connected. The water path is formed such that the cooling water flows in order of the first cooling water path, the oil-cooler water path, and then the second cooling water path. Thus, since a pipe for a water path through which the cooling water flows is not needed around the oil cooler, in particular, at a part between the inverter and the oil cooler, the weight and the size of the electric vehicle driving device can be reduced. In addition, since a water path through which the cooling water flows is not provided inside the gear box which is a waterproof region of the electric vehicle driving device, entry of the cooling water into the waterproof region can be prevented. In addition, since a pipe is not provided around the oil cooler, there is no pipe protruding part around the oil cooler. Thus, it is possible to provide the electric vehicle driving device for which troublesome pipe work and a pipe routing space are not needed and which can be easily mounted into the electric vehicle.

### BRIEF DESCRIPTION OF THE DRAWINGS

FIGS. 1A to 1C are plan views schematically showing an electric vehicle driving device according to the first embodiment of the present disclosure;

FIG. 2 is a front view schematically showing the electric vehicle driving device according to the first embodiment;

FIG. 3 is a side view schematically showing the electric vehicle driving device according to the first embodiment;

FIG. 4 is an exploded plan view showing a major part of the electric vehicle driving device according to the first embodiment;

FIGS. 5A to 5C are side views showing a major part of the electric vehicle driving device according to the first embodiment;

FIG. 6 is an exploded plan view showing a major part of another electric vehicle driving device according to the first embodiment;

FIG. 7 is a side view showing a major part of another electric vehicle driving device according to the first embodiment;

FIG. 8 is an exploded plan view showing a major part of another electric vehicle driving device according to the first embodiment;

FIG. 9 is a side view showing a major part of another electric vehicle driving device according to the first embodiment;

FIG. 10 is a side view showing a major part of an electric vehicle driving device according to the second embodiment of the present disclosure;

FIG. 11 is a plan view showing a major part of the electric vehicle driving device according to the second embodiment;

FIG. 12 is a side view showing a major part of an electric vehicle driving device according to the third embodiment of the present disclosure;

FIG. 13 is a plan view showing a major part of the electric vehicle driving device according to the third embodiment;

FIGS. 14A and 14B are sectional views showing a major part of an electric vehicle driving device according to the fourth embodiment of the present disclosure;

FIGS. 15A and 15B are sectional views showing a major part of another electric vehicle driving device according to the fourth embodiment; and

FIGS. 16A and 16B are sectional views showing a major part of another electric vehicle driving device according to the fourth embodiment.

### DETAILED DESCRIPTION OF THE EMBODIMENTS

Hereinafter, an electric vehicle driving device according to embodiments of the present disclosure will be described with reference to the drawings. In the drawings, the same or corresponding members and parts are denoted by the same reference characters, to give description. An electric vehicle in the present disclosure is not limited to an automobile and refers to mobility means used as traffic means, transportation means, movement means, or the like, including a two-wheel vehicle.

### First Embodiment

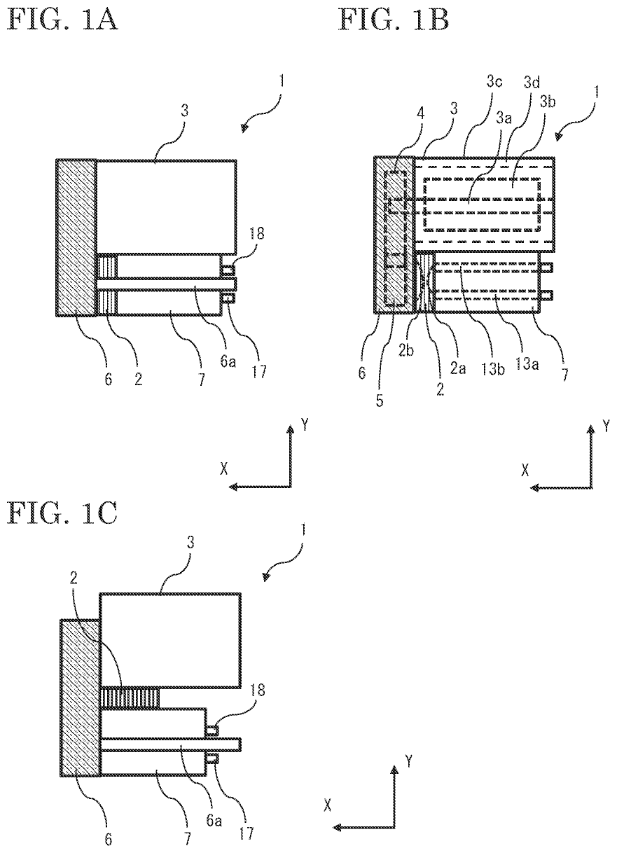

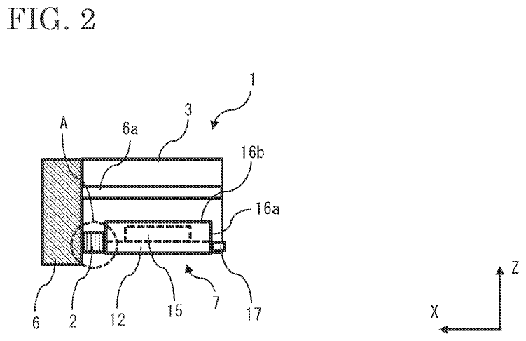

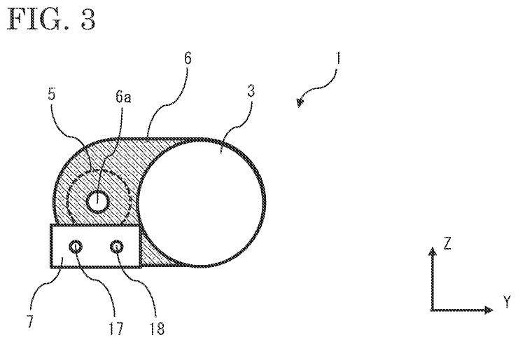

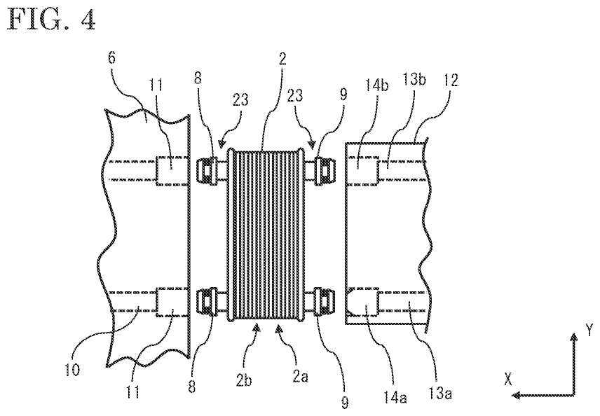

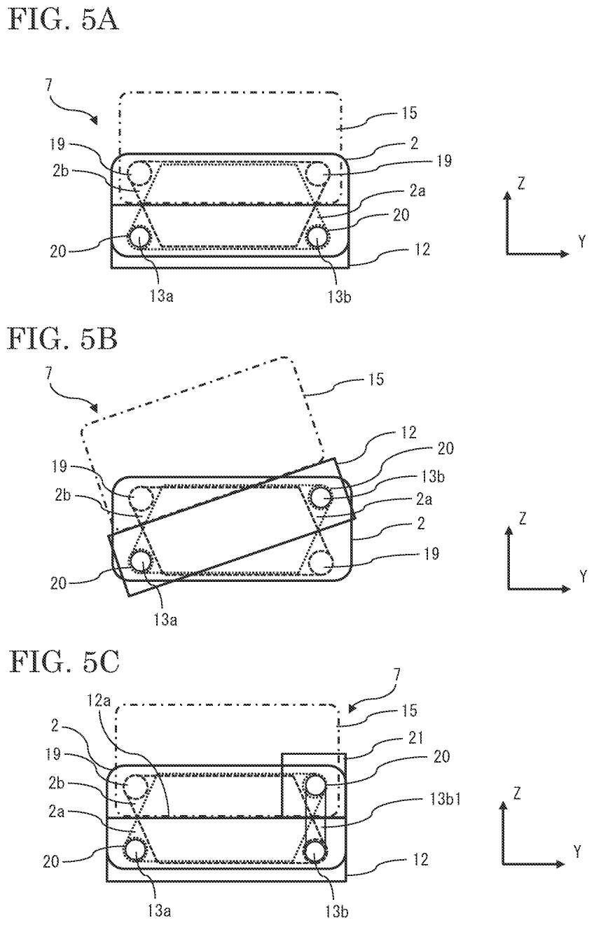

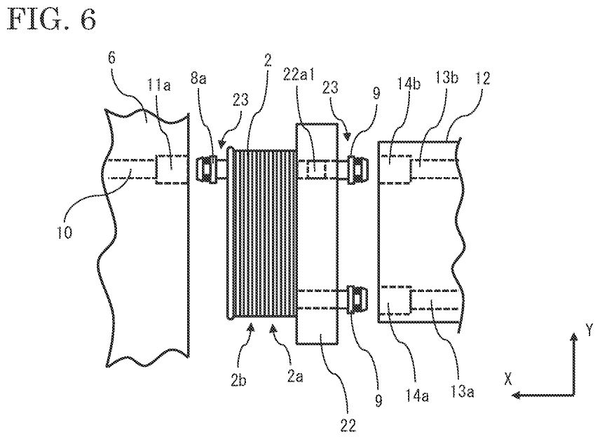

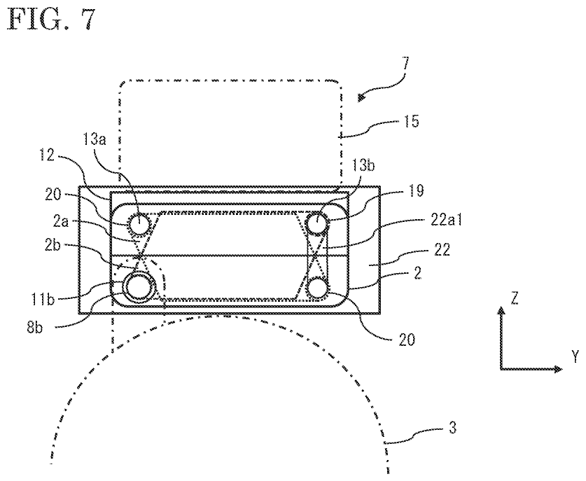

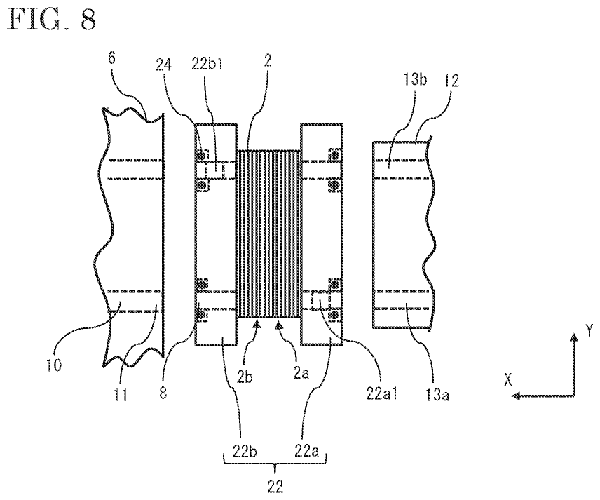

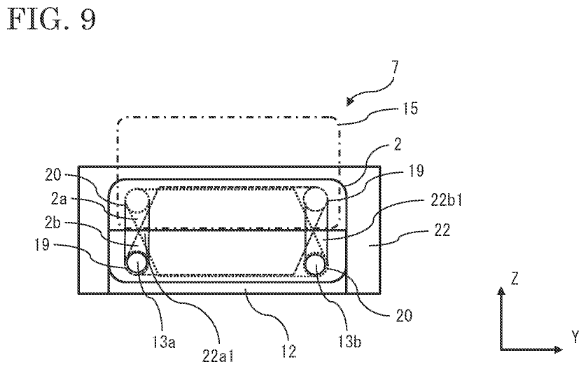

FIG. 1A is a plan view schematically showing an electric vehicle driving device 1 according to the first embodiment of the present disclosure. FIG. 1B is a plan view schematically showing the electric vehicle driving device 1 with a drive shaft 6a removed from the electric vehicle driving device 1. FIG. 1C is a plan view schematically showing another electric vehicle driving device 1. FIG. 2 is a front view schematically showing the electric vehicle driving device 1 as seen from the advancement direction of an electric vehicle. FIG. 3 is a side view schematically showing the electric vehicle driving device 1 and shows another side in an X direction. FIG. 4 is an exploded plan view showing a major part of the electric vehicle driving device 1 and shows an attachment structure for an oil cooler 2 at part A (part enclosed by broken line) in FIG. 2. FIG. 5A is a side view showing a major part of the electric vehicle driving device 1 as seen from the other side in the X direction through both of an oil cooler 2 and a water-cooled plate 12. FIG. 5B is a side view showing a major part of another electric vehicle driving device 1 as seen at the same part and in the same direction as in FIG. 5A. FIG. 5C is a side view showing a major part of still another electric vehicle driving device 1 as seen at the same part and in the same direction as in FIG. 5A. FIG. 6 is an exploded plan view showing a major part of another electric vehicle driving device 1 and shows an attachment structure for the oil cooler 2 at a position equivalent to part A in FIG. 2. FIG. 7 is a side view showing a major part of another electric vehicle driving device 1 as seen from the other side in the X direction in FIG. 6. FIG. 8 is an exploded plan view showing a major part of another electric vehicle driving device 1 and shows an attachment structure for the oil cooler 2 at a position equivalent to part A in FIG. 2. FIG. 9 is a side view showing a major part of another electric vehicle driving device 1 as seen from the other side in the X direction in FIG. 8. The electric vehicle driving device 1 mounted to the electric vehicle is a device that transmits rotation of a rotary shaft 3a of a motor 3 controlled by an inverter 7 to the drive shaft 6a via a speed reduction mechanism 4 and a differential mechanism 5.

### <Electric Vehicle Driving Device 1>

As shown in FIG. 1B, the electric vehicle driving device 1 includes the motor 3, a gear box 6 storing the speed reduction mechanism 4 connected to the motor 3, and the differential mechanism 5 connected to the speed reduction mechanism 4, the inverter 7 which is electrically connected to the motor 3 and converts power, and the oil cooler 2 which oil-cools the motor 3. Here, directions are defined as follows. A direction in which the oil cooler 2 is arranged side by side with the inverter 7 in FIG. 1A and FIG. 2 is defined as one side in the X direction, a direction which is perpendicular to the X direction and in which the motor 3 is provided with respect to the inverter 7 in FIG. 1A and FIG. 3 is defined as one side in a Y direction, and a direction perpendicular to the X direction and the Y direction is defined as a Z direction. In the drawings, a direction indicated by each arrow is one side and a direction opposite to the direction indicated by each arrow is another side.

The gear box 6 is provided on the one side in the X direction of the motor 3 and the oil cooler 2. In the present embodiment, as shown in FIG. 1A, the motor 3 and the gear box 6 are provided so as to be connected in an L shape. The oil cooler 2 and the inverter 7 are provided on the other side in the Z direction at a part between the motor 3 and the gear box 6 arranged in the L shape. The arrangement configuration of the members in the electric vehicle driving device 1 is not limited to the above one. As described later, any configuration may be adopted as long as the oil cooler 2 is provided in contact with the inverter 7. For example, as shown in FIG. 1C, the oil cooler 2 may be provided on the one side in the Y direction of the inverter 7 and the oil cooler 2 is located so as to be interposed between the inverter 7 and the motor 3.

As shown in FIG. 1B, the motor 3 includes a stator 3d having a core and a coil, a rotor 3b provided on the inner side of the stator 3d, and a housing 3c storing the stator 3d and the rotor 3b. The rotary shaft 3a of the rotor 3b is rotatably supported by a bearing and is provided so as to be rotatable coaxially with the stator 3d. The housing 3c is formed by casting or forging of metal such as aluminum, for example.

The gear box 6 stores the speed reduction mechanism 4 connected to the rotary shaft 3a, and the differential mechanism 5 connected to the speed reduction mechanism 4. The speed reduction mechanism 4 outputs rotation with the speed reduced from rotation of the rotary shaft 3a of the motor 3. The differential mechanism 5 absorbs a speed difference between left and right tires. The gear box 6 is formed by casting or forging of metal such as aluminum, for example.

One side of the drive shaft 6a is connected to the differential mechanism 5. The drive shaft 6a extends in the X direction. Tires (not shown) are attached to both-side extending parts of the drive shaft 6a. Since the housing 3c and the gear box 6 are formed using aluminum, the weights and the costs thereof can be reduced and their complicated shapes can be easily formed. In addition, forming these parts from the same material leads to a measure against electric corrosion. The material of these is not limited to aluminum and may be a resin material.

### <Inverter 7 and Oil Cooler 2>

The configurations of the inverter 7 and the oil cooler 2 which are a major part of the present disclosure will be described. The inverter 7 performs DC-AC conversion between a DC power supply (not shown) and windings of the stator 3d for a plurality of phases. The inverter 7 is fixed to the motor 3, for example. As shown in FIG. 1B, the inverter 7 has a first cooling water path 13a and a second cooling water path 13b through which cooling water flows.

The oil cooler 2 has an oil-cooler water path 2a through which the cooling water flows, and an oil-cooler oil path 2b through which oil flows. FIG. 1B schematically shows these paths. The oil-cooler water path 2a and the oil-cooler oil path 2b are arranged separately from each other without communicating with each other. The oil cooler 2 is an oil-cooling water heat exchanger for performing heat exchange between the oil-cooler water path 2a and the oil-cooler oil path 2b via a solid wall. The oil-cooler water path 2a and the oil-cooler oil path 2b are arranged so as to be stacked alternately, as shown in FIG. 4, for example. As shown in FIG. 5A, the oil cooler 2 has oil headers 19 and cooling water headers 20 on both sides in the Y direction. The stacked oil-cooler water path 2a parts are connected to the cooling water headers 20, so that flow paths connected in parallel are formed. The stacked oil-cooler oil path 2b parts are connected to the oil headers 19, so that flow paths connected in parallel are formed. The motor 3 and the gear box 6 have an oil path 10 connected to the oil-cooler oil path 2b. As the cooling water, water is used, for example. However, without limitation thereto, an antifreeze (LLC) containing ethylene glycol as a main component may be used.

As shown in FIG. 1B, the oil cooler 2 is provided in contact with the inverter 7. At the contact part, the first cooling water path 13a and the oil-cooler water path 2a are connected, and the second cooling water path 13b and the oil-cooler water path 2a are connected. A water path is formed such that the cooling water flows in order of the first cooling water path 13a, the oil-cooler water path 2a, and then the second cooling water path 13b. As shown in FIG. 2, the part of the inverter 7 contacting with the oil cooler 2 is the water-cooled plate 12 which is a part of the inverter 7 where the first cooling water path 13a and the second cooling water path 13b are formed.

With this configuration, since a pipe for a water path through which the cooling water flows is not needed around the oil cooler 2, in particular, at a part between the inverter 7 and the oil cooler 2, the weight and the size of the electric vehicle driving device 1 can be reduced. In addition, since a water path through which the cooling water flows is not provided inside the gear box 6 which is a waterproof region of the electric vehicle driving device 1, entry of the cooling water into the waterproof region can be prevented. In addition, since a pipe is not provided around the oil cooler 2, there is no pipe protruding part around the oil cooler 2. Thus, it is possible to provide the electric vehicle driving device 1 for which troublesome pipe work and a pipe routing space are not needed and which can be easily mounted into the electric vehicle. In addition, since there is no pipe protruding part around the oil cooler 2, the volume efficiency of the electric vehicle driving device 1 can be improved.

In the present embodiment, the oil cooler 2 is provided in contact with the motor 3 or the gear box 6 on the side opposite to the inverter 7. At the contact part, the oil path 10 and the oil-cooler oil path 2b are connected. The oil cooler 2 is located so as to be interposed between the inverter 7 and the motor 3 or the gear box 6. In the configuration shown in FIG. 2, the oil cooler 2 is located so as to be interposed between the inverter 7 and the gear box 6. In the configuration shown in FIG. 1C, the oil cooler 2 is located so as to be interposed between the inverter 7 and the motor 3.

With this configuration, since a pipe for a water path through which the cooling water flows is not needed around the oil cooler 2, in particular, at a part between the inverter 7 and the oil cooler 2, and a pipe for an oil path through which the oil flows is not needed at a part between the motor 3 or the gear box 6 and the oil cooler 2, the weight and the size of the electric vehicle driving device 1 can be reduced. In addition, since a pipe is not provided around the oil cooler 2, there is no pipe protruding part around the oil cooler 2. Thus, it is possible to provide the electric vehicle driving device 1 for which troublesome pipe work and a pipe routing space are not needed and which can be easily mounted into the electric vehicle. In addition, since there is no pipe protruding part around the oil cooler 2, the volume efficiency of the electric vehicle driving device 1 can be improved.

An example of an attachment structure for the oil cooler 2 will be described with reference to FIG. 4. Two oil-cooler-oil-path connection portions 8 are provided on the one side in the X direction of the oil cooler 2, and two oil-cooler-water-path connection portions 9 are provided on the other side in the X direction of the oil cooler 2. The oil-cooler-oil-path connection portions 8 are ends of the oil-cooler oil path 2b. The oil-cooler-water-path connection portions 9 are ends of the oil-cooler water path 2a. The oil path 10 provided to the gear box 6 has two oil path connection portions 11 on the other side in the X direction. The oil path connection portions 11 are ends of the oil path 10. The first cooling water path 13a has a cooling-water-path connection portion 14a which is an end of the first cooling water path 13a, on the other side in the X direction, and the second cooling water path 13b has a cooling-water-path connection portion 14b which is an end of the second cooling water path 13b, on the other side in the X direction.

The oil-cooler-oil-path connection portions 8 are respectively connected to the oil path connection portions 11. By these connections, the oil-cooler oil path 2b and the oil path 10 are connected, the gear box 6 and the oil cooler 2 contact with each other, and the oil cooler 2 is fixed to the gear box 6. One of the oil-cooler-water-path connection portions 9, and the cooling-water-path connection portion 14a, are connected, and the other of the oil-cooler-water-path connection portions 9, and the cooling-water-path connection portion 14b, are connected. By these connections, the oil-cooler water path 2a, and the first cooling water path 13a and the second cooling water path 13b, are connected, the inverter 7 and the oil cooler 2 contact with each other, and the oil cooler 2 is fixed to the inverter 7.

In the present embodiment, nipples 23 are provided as the oil-cooler-oil-path connection portions 8 and the oil-cooler-water-path connection portions 9. The oil path connection portions 11, the cooling-water-path connection portion 14a, and the cooling-water-path connection portion 14b have recesses to be fitted to the nipples 23. Since these connection portions are connected by such fitting structures, in-plane-direction displacement of contact surfaces is suppressed, whereby both members to contact with each other can be easily fixed. The first cooling water path 13a and the oil-cooler water path 2a, the second cooling water path 13b and the oil-cooler water path 2a, and the oil path 10 and the oil-cooler oil path 2b, may be connected by one-touch connector structures. As shown in a fitting structure at the lower right in FIG. 4, in the one-touch connector structure, one side of connection is a socket and another side is a plug. The nipple 23 on the plug side is provided with a dripping preventing mechanism such as a check-valve-equipped structure which is detachable in a simple way. The dripping preventing mechanism may be an O ring. With this configuration, dripping of the oil or the cooling water can be suppressed at the time of detachment/replacement of the oil cooler 2, and entry of trash into the oil-cooler water path 2a or the oil-cooler oil path 2b can be prevented. In addition, assemblability of the electric vehicle driving device 1 can be improved.

The details of the configuration of the inverter 7 will be described. As shown in FIG. 2, the inverter 7 has an electric component 15, and the water-cooled plate 12 inside which the first cooling water path 13a and the second cooling water path 13b are formed. The electric component 15 includes electric and electronic components that convert power and perform drive control of the motor 3. The electric component 15 is mounted on the water-cooled plate 12. The electric component 15 is surrounded by a case 16a formed in a tubular shape. An opened part on the other side in the Z direction of the case 16a contacts with the water-cooled plate 12. An opened part on the one side in the Z direction of the case 16a is covered by a cover 16b. By the case 16a and the cover 16b, the electric component 15 is kept in a waterproof state against the outside and is isolated and protected from the outside. The case 16a and the cover 16b are formed from metal such as aluminum, for example.

The inverter 7 has a cooling water entrance 17 through which the cooling water flows into the first cooling water path 13a, and a cooling water exit 18 through which the cooling water is sent out from the second cooling water path 13b. In the present embodiment, as shown in FIG. 1A, the cooling water entrance 17 and the cooling water exit 18 are provided on the other side in the X direction of the water-cooled plate 12. Arrangement of the cooling water entrance 17 and the cooling water exit 18 is not limited thereto. For example, they may be provided on the other side in the Z direction of the water-cooled plate 12.

The cooling water entrance 17 and the cooling water exit 18 are connected to an external-water-cooled system. Low-temperature cooling water is supplied from the external-water-cooled system to the cooling water entrance 17. The external-water-cooled system is composed of a radiator and a cooling water pump, for example, and the cooling water in the external-water-cooled system circulates through the first cooling water path 13a, the oil-cooler water path 2a, and the second cooling water path 13b by driving of a cooling water pump. When the cooling water flows through the first cooling water path 13a and the second cooling water path 13b, heat generated due to operation of the electric component 15 is absorbed by the cooling water via a solid wall of the water-cooled plate 12. The cooling water whose temperature has increased through heat absorption is discharged through the cooling water exit 18. The temperature-increased cooling water dissipates heat at the radiator to the surrounding air.

The cooling water entrance 17 and the cooling water exit 18 are nipples, for example, and are connected to pipes provided to the external-water-cooled system, via a seal structure such as an O ring or a packing. The attachment positions and structures of the cooling water entrance 17 and the cooling water exit 18 are not limited to the above ones as long as they are connected to the external-water-cooled system via pipes and the cooling water is supplied or discharged. In addition, without limitation to the configuration in which the cooling water is discharged through the cooling water exit 18 to the external-water-cooled system, the cooling water may be sent out through the cooling water exit 18 to the motor 3 or another device (charger, booster, etc.), to cool the motor 3 or the other device.

The details of the connection configuration between the inverter 7 and the oil cooler 2 will be described with reference to FIG. 5A to FIG. 5C. In these drawings, the electric component 15 is indicated by a dotted-dashed line, the oil-cooler water path 2a is indicated by a dot line, and the oil-cooler oil path 2b is indicated by a broken line. In FIG. 5A, the oil headers 19 and the cooling water headers 20 are respectively arranged in the same order side by side in the Y direction. The oil-cooler water paths 2a and the oil-cooler oil paths 2b stacked in the X direction are each formed to extend in the Z direction, as seen in the X direction. In FIG. 5B, the oil headers 19 and the cooling water headers 20 are arranged in a reverse order such that each oil header 19 and each cooling water header 20 are side by side in the Y direction. The oil-cooler water paths 2a and the oil-cooler oil paths 2b stacked in the X direction are formed to extend obliquely such that both paths cross each other, as seen in the X direction. In a case where the first cooling water path 13a and the second cooling water path 13b are arranged side by side on the same plane, in the configuration of the oil cooler 2 shown in FIG. 5A, both of the oil cooler 2 and the inverter 7 can be arranged on an XY plane. However, in the configuration of the oil cooler 2 shown in FIG. 5B, the inverter 7 is arranged to be inclined from an XY plane relative to the oil cooler 2. The oil cooler 2 shown in FIG. 5B is high in the heat exchange efficiency between the oil and the cooling water, but is low in the volume efficiency of the oil cooler 2 and the inverter 7 because the inverter 7 is arranged to be inclined.

Another configuration shown in FIG. 5C will be described. In FIG. 5C, the configuration of the oil cooler 2 is the same as the configuration of the oil cooler 2 shown in FIG. 5B, and the configuration of the water-cooled plate 12 is different from that in FIG. 5B. The water-cooled plate 12 has a protruding portion 21 protruding in the Z direction from a cooling surface 12a on which the electric component 15 is mounted. The protruding portion 21 has a second cooling-water-path connection portion 13b1 connected to the second cooling water path 13b. The second cooling-water-path connection portion 13b1 and the cooling water header 20 are connected at the oil-cooler-water-path connection portion 9. The second cooling water path 13b, the second cooling-water-path connection portion 13b1, and the cooling water header 20 form an S-shaped flow path as seen in the Y direction, and both of the oil cooler 2 and the inverter 7 can be arranged on an XY plane. With this configuration, even in the oil cooler 2 having the flow path configuration shown in FIG. 5B in which the heat exchange efficiency between the oil and the cooling water is high, both of the oil cooler 2 and the inverter 7 can be arranged on an XY plane, whereby arrangement of the oil cooler 2 and the inverter 7 with high volume efficiency can be realized.

### <Modification 1>

With reference to FIG. 6 and FIG. 7, a configuration in modification 1 will be described. As shown in FIG. 6, the oil cooler 2 has an end plate 22 on a side where the inverter 7 is provided on the other side in the X direction. At the end plate 22, the two oil-cooler-water-path connection portions 9 are provided on the other side in the X direction. The oil-cooler-water-path connection portions 9 are the nipples 23, for example. The end plate 22 has therein an end plate water path 22a1 connecting the oil-cooler water path 2a, and the first cooling water path 13a and the second cooling water path 13b. The end plate water path 22a1 is bent in an S shape in the X direction inside the end plate 22, whereby arrangement of the oil cooler 2 and the inverter 7 with high volume efficiency can be realized as in FIG. 5C.

In modification 1, the motor 3 is provided on the other side in the X direction with respect to the oil cooler 2. The oil cooler 2 has a first oil-cooler-oil-path connection portion 8a on the one side in the X direction, and a second oil-cooler-oil-path connection portion 8b on the other side in the X direction. In FIG. 6, the second oil-cooler-oil-path connection portion 8b is not shown because the second oil-cooler-oil-path connection portion 8b is located on the other side in the Z direction of the oil-cooler-water-path connection portion 9. The first oil-cooler-oil-path connection portion 8a and an oil path connection portion 11a of the gear box 6 are connected, and the second oil-cooler-oil-path connection portion 8b and an oil path connection portion 11b of the motor 3 are connected. The oil flows in order of the gear box 6, the oil cooler 2, and then the motor 3. As shown in FIG. 7, the electric vehicle driving device 1 may have a configuration in which the motor 3 is provided on the other side in the X direction with respect to the oil cooler 2 and the oil flows in order of the gear box 6, the oil cooler 2, and then the motor 3.

### <Modification 2>

With reference to FIG. 8 and FIG. 9, a configuration in the modification 2 will be described. As shown in FIG. 8, the oil cooler 2 has the end plates 22 on both of the one side in the X direction and the other side in the X direction. The end plate 22 provided on the other side in the X direction is an end plate 22a, and the end plate 22 provided on the one side in the X direction is an end plate 22b. As a configuration of a water path inside the end plate 22a, the end plate 22a has two end plate water paths 22a1. The end plate water path 22a1 on the other side in the Y direction is the end plate water path 22a1 bent in an S shape in the X direction. The end plate 22a ensures a liquid-tight state for connection with the first cooling water path 13a and the second cooling water path 13b provided in the water-cooled plate 12, by contact via O rings 24, instead of nipples.

The end plate 22b is provided with two oil-cooler-oil-path connection portions 8 on the one side in the X direction. The oil-cooler-oil-path connection portions 8 are parts ensuring a liquid-tight state by contact with the oil path connection portions 11 via O rings 24. The end plate 22b has therein two end plate oil paths 22b1 connecting the oil path 10 of the gear box 6 and the oil-cooler oil path 2b. Inside the end plate 22b, the end plate oil path 22b1 on the one side in the Y direction is bent in an S shape in the X direction as with the end plate water path 22a1 on the other side in the Y direction of the end plate 22a, whereby the oil path connection portions 11 are provided side by side in the Y direction. Thus, arrangement of the oil cooler 2 and the gear box 6 with high volume efficiency can be realized.

As described above, in the electric vehicle driving device 1 according to the first embodiment, the inverter 7 has the first cooling water path 13a and the second cooling water path 13b through which the cooling water flows. The oil cooler 2 has the oil-cooler water path 2a through which the cooling water flows. The oil cooler 2 is provided in contact with the inverter 7. At the contact part, the first cooling water path 13a and the oil-cooler water path 2a are connected, and the second cooling water path 13b and the oil-cooler water path 2a are connected. A water path is formed such that the cooling water flows in order of the first cooling water path 13a, the oil-cooler water path 2a, and then the second cooling water path 13b. Thus, since a pipe for a water path through which the cooling water flows is not needed around the oil cooler 2, in particular, at a part between the inverter 7 and the oil cooler 2, the weight and the size of the electric vehicle driving device 1 can be reduced. In addition, since a water path through which the cooling water flows is not provided inside the gear box 6 which is a waterproof region of the electric vehicle driving device 1, entry of the cooling water into the waterproof region can be prevented. In addition, since a pipe is not provided around the oil cooler 2, there is no pipe protruding part around the oil cooler 2. Thus, it is possible to provide the electric vehicle driving device 1 for which troublesome pipe work and a pipe routing space are not needed and which can be easily mounted into the electric vehicle. In addition, since there is no pipe protruding part around the oil cooler 2, the volume efficiency of the electric vehicle driving device 1 can be improved.

The oil cooler 2 may be provided in contact with the motor 3 or the gear box 6 on the side opposite to the inverter 7. At the contact part, the oil path 10 and the oil-cooler oil path 2b may be connected. The oil cooler 2 may be located so as to be interposed between the inverter 7 and the motor 3 or the gear box 6. Thus, since a pipe for a water path through which the cooling water flows is not needed around the oil cooler 2, in particular, at a part between the inverter 7 and the oil cooler 2, and a pipe for an oil path through which the oil flows is not needed at a part between the motor 3 or the gear box 6 and the oil cooler 2, the weight and the size of the electric vehicle driving device 1 can be reduced. In addition, since a pipe is not provided around the oil cooler 2, there is no pipe protruding part around the oil cooler 2. Thus, it is possible to provide the electric vehicle driving device 1 for which troublesome pipe work and a pipe routing space are not needed and which can be easily mounted into the electric vehicle. In addition, since there is no pipe protruding part around the oil cooler 2, the volume efficiency of the electric vehicle driving device 1 can be improved. The first cooling water path 13a and the oil-cooler water path 2a, the second cooling water path 13b and the oil-cooler water path 2a, and the oil path 10 and the oil-cooler oil path 2b, may be connected by one-touch connector structures. Thus, dripping of the oil or the cooling water can be suppressed at the time of detachment/replacement of the oil cooler 2, and entry of trash into the oil-cooler water path 2a or the oil-cooler oil path 2b can be prevented. In addition, assemblability of the electric vehicle driving device 1 can be improved.

### Second Embodiment

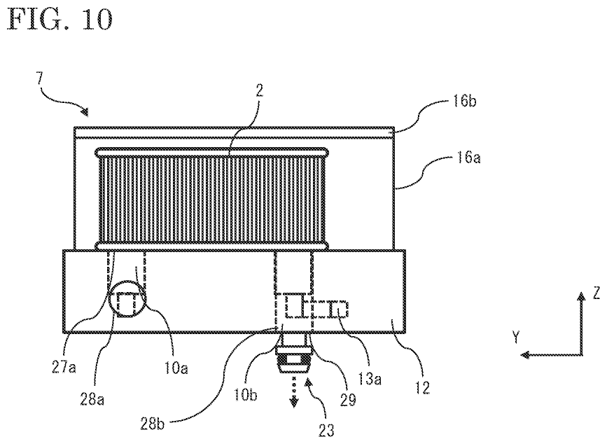

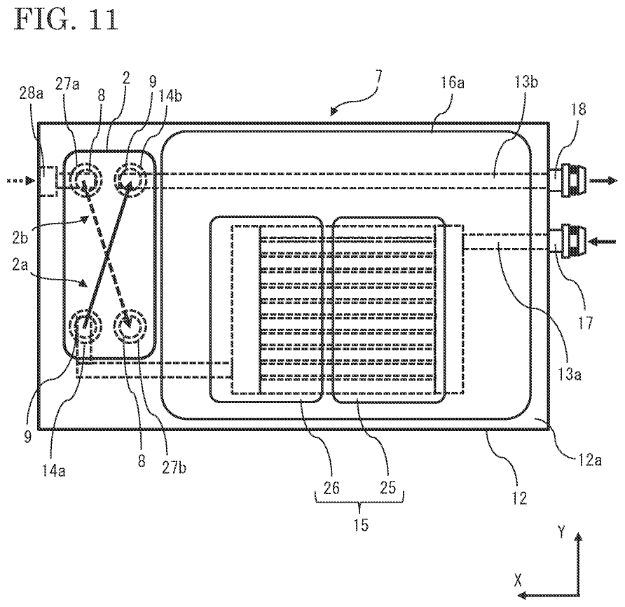

An electric vehicle driving device 1 according to the second embodiment of the present disclosure will be described. FIG. 10 is a side view showing the oil cooler 2 and the inverter 7 which are a major part of the electric vehicle driving device 1 according to the second embodiment and shows the one side in the X direction. FIG. 11 is a plan view showing the oil cooler 2 and the inverter 7 which are a major part of the electric vehicle driving device 1 with the cover 16b removed. In the electric vehicle driving device 1 according to the second embodiment, the oil cooler 2 is provided on the cooling surface 12a of the water-cooled plate 12.

As shown in FIG. 11, the inverter 7 has the electric component 15, and the water-cooled plate 12 inside which the first cooling water path 13a and the second cooling water path 13b are formed. The water-cooled plate 12 has the cooling surface 12a on which the electric component 15 is mounted. The oil cooler 2 is provided in contact with the cooling surface 12a and arranged side by side with the electric component 15.

The electric component 15 is covered by the case 16a and the cover 16b. In the present embodiment, the oil cooler 2 is provided on the one side in the X direction of the case 16a. Arrangement of the oil cooler 2 is not limited thereto and the oil cooler 2 may be provided on the one side in the Y direction of the case 16a, for example. The oil cooler 2 is fixed to the cooling surface 12a by soldering or brazing, for example. The oil cooler 2 may be fixed to the cooling surface 12a by a bolt. In a case where the oil cooler 2 has the oil-cooler-oil-path connection portion 8 or the oil-cooler-water-path connection portion 9 on the cooling surface 12a side, a seal structure using an O ring or a packing is provided at a connection part with the oil path or the cooling water path so that the oil or the cooling water does not leak between the oil cooler 2 and the cooling surface 12a.

As described above, since the oil cooler 2 is provided in contact with the cooling surface 12a, and the oil cooler 2 and the electric component 15 are arranged side by side with each other, a pipe between the inverter 7 and the oil cooler 2 is not needed and a connection portion between the inverter 7 and the oil cooler 2 can be simplified, whereby the size and the weight of the electric vehicle driving device 1 can be reduced. In addition, since the inverter 7 part and the oil cooler 2 part of the electric vehicle driving device 1 have an integrated structure, workability in attachment of the electric vehicle driving device 1 to the electric vehicle can be improved. In addition, since the inverter 7 part and the oil cooler 2 part are integrated, the strengths and vibration resistances of the inverter 7 and the oil cooler 2 can be improved.

In the present embodiment, the inverter 7 has a power module 25 and a capacitor 26 arranged adjacently to the first cooling water path 13a, and the cooling water entrance 17 through which the cooling water flows into the first cooling water path 13a. The inverter 7 further has the cooling water exit 18 through which the cooling water is sent out from the second cooling water path 13b. In the present embodiment, the cooling water entrance 17 and the cooling water exit 18 are provided on the other side in the X direction of the water-cooled plate 12. The cooling water entrance 17 and the cooling water exit 18 are nipples, for example. The power module 25 and the capacitor 26 are the electric components 15 mounted on the cooling surface 12a. The electric components 15 mounted on the cooling surface 12a are not limited to the power module 25 and the capacitor 26, and another electric component such as a transformer may be provided on the cooling surface 12a.

A cooling water flow path through which the cooling water circulates will be described. In FIG. 11, the direction in which the cooling water flows is indicated by solid-line arrows. The cooling-water-path connection portion 14a of the first cooling water path 13a and the oil-cooler-water-path connection portion 9 are connected at the cooling surface 12a, and the cooling-water-path connection portion 14b of the second cooling water path 13b and the oil-cooler-water-path connection portion 9 are connected at the cooling surface 12a. Low-temperature cooling water is supplied from the external-water-cooled system to the cooling water entrance 17. The cooling water circulates in order of the first cooling water path 13a, the oil-cooler water path 2a, and then the second cooling water path 13b by driving of the cooling water pump (not shown). The low-temperature cooling water flows through the first cooling water path 13a first. Therefore, for enabling more efficient cooling, it is desirable to form the first cooling water path 13a in accordance with the location of the electric component 15 that readily generates heat.

In the present embodiment, the first cooling water path 13a is provided such that the cooling water flowing inward through the cooling water entrance 17 passes in order of the power module 25 and then the capacitor 26 through a part of the first cooling water path 13a to which the power module 25 and the capacitor 26 are arranged adjacently. Of the electric components 15, the component that most readily generates heat is the power module 25. The capacitor 26 is the electric component 15 which generates heat and whose permissible temperature is low. With this configuration, the low-temperature cooling water flows in order of the power module 25 and then the capacitor 26, whereby the power module 25 and the capacitor 26 can be more efficiently cooled.

After cooling the power module 25 and the capacitor 26, the cooling water undergoes heat exchange with the oil, and then flows through the second cooling water path 13b. Since the temperature-increased cooling water flows through the second cooling water path 13b, it is preferable that an electric component whose permissible temperature is high and an electric component whose heat generation amount is small are placed there.

In the present embodiment, a part of the oil path 10 is provided inside the water-cooled plate 12. In FIG. 10 and FIG. 11, the direction in which the oil flows is indicated by broken-line arrows. The oil-cooler-oil-path connection portion 8 on the upstream side where the oil flows inward, and a first plate-oil-path connection portion 27a provided at the cooling surface 12a of the water-cooled plate 12 with which the oil cooler 2 contacts, are connected. A second plate-oil-path connection portion 28a provided at a side surface of the water-cooled plate 12 with which the gear box 6 contacts, and the oil path connection portion 11 of the gear box 6, are connected. A plate oil path 10a is formed at a part of the water-cooled plate 12 between the first plate-oil-path connection portion 27a and the second plate-oil-path connection portion 28a. The plate oil path 10a is an oil path formed in an L shape as seen in the Y direction. Via the plate oil path 10a, the oil-cooler-oil-path connection portion 8 and the oil path connection portion 11 are connected so that the oil can pass therebetween.

The oil-cooler-oil-path connection portion 8 on the downstream side where the oil is sent out, and a first plate-oil-path connection portion 27b provided at the cooling surface 12a of the water-cooled plate 12 with which the oil cooler 2 contacts, are connected. A second plate-oil-path connection portion 28b provided at a surface on the other side in the Z direction of the water-cooled plate 12 where the oil is discharged to the outside, has an opening 29. A plate oil path 10b is formed at a part of the water-cooled plate 12 between the first plate-oil-path connection portion 27b and the second plate-oil-path connection portion 28b. In the present embodiment, the nipple 23 is provided at the opening 29, and the nipple 23 and an oil path connection portion provided to the motor 3 are connected.

In the present embodiment, the configuration in which the oil-cooler-oil-path connection portions 8 are connected to the outside oil path connection portions via the plate oil paths 10a, 10b, has been shown. However, the present disclosure is not limited thereto. Without providing each plate oil path 10a, 10b, the oil-cooler-oil-path connection portion 8 may be exposed and the oil-cooler-oil-path connection portion 8 and the outside oil path connection portion may be directly connected to each other.

As described above, in the electric vehicle driving device 1 according to the second embodiment, the inverter 7 has the electric component 15, and the water-cooled plate inside which the first cooling water path 13a and the second cooling water path 13b are formed. The water-cooled plate 12 has the cooling surface 12a on which the electric component 15 is mounted. The oil cooler 2 is provided in contact with the cooling surface 12a and arranged side by side with the electric component 15. Thus, a pipe between the inverter 7 and the oil cooler 2 is not needed and a connection portion between the inverter 7 and the oil cooler 2 can be simplified, whereby the size and the weight of the electric vehicle driving device 1 can be reduced. In addition, since the inverter 7 part and the oil cooler 2 part of the electric vehicle driving device 1 have an integrated structure, workability in attachment of the electric vehicle driving device 1 to the electric vehicle can be improved. In addition, since the inverter 7 part and the oil cooler 2 part are integrated, the strengths and vibration resistances of the inverter 7 and the oil cooler 2 can be improved.

The inverter 7 may have the power module 25 and the capacitor 26 arranged adjacently to the first cooling water path 13a, and the cooling water entrance 17 through which the cooling water flows into the first cooling water path 13a. The first cooling water path 13a may be provided such that the cooling water flowing inward through the cooling water entrance 17 passes in order of the power module 25 and then the capacitor 26 through a part of the first cooling water path 13a to which the power module 25 and the capacitor 26 are arranged adjacently. Thus, of the electric components 15, the component that most readily generates heat is the power module 25, and the capacitor 26 is also the electric component 15 that readily generates heat, and accordingly, the cooling water flows in order of the power module 25 and then the capacitor 26, whereby the power module 25 and the capacitor 26 can be more efficiently cooled.

### Third Embodiment

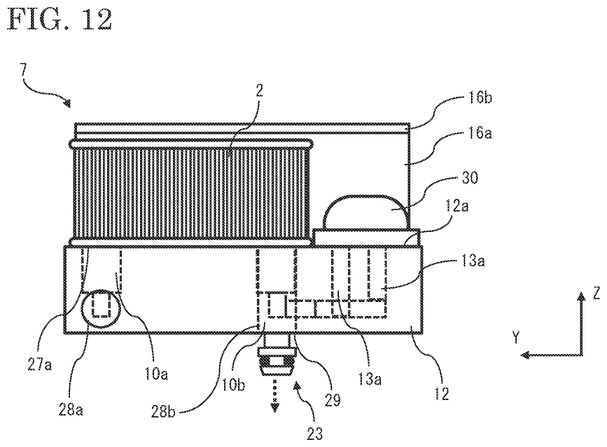

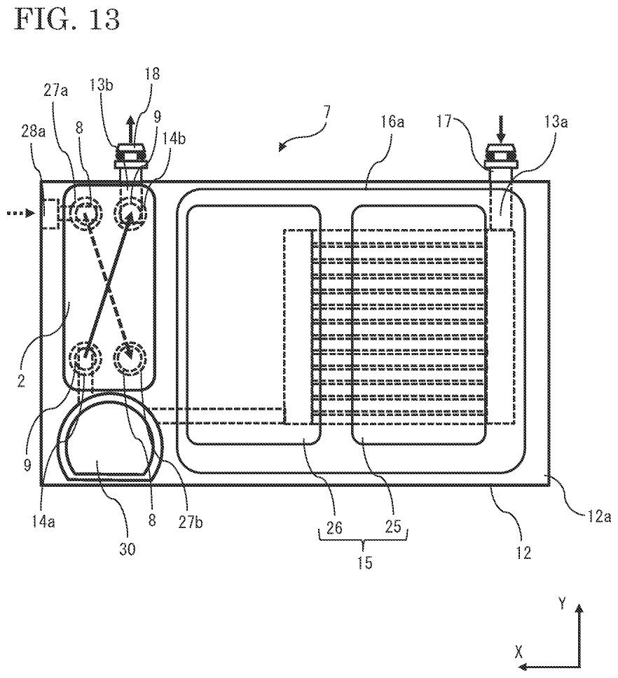

An electric vehicle driving device 1 according to the third embodiment of the present disclosure will be described. FIG. 12 is a side view showing the oil cooler 2 and the inverter 7 which are a major part of the electric vehicle driving device 1 according to the third embodiment and shows the one side in the X direction. FIG. 13 is a plan view showing the oil cooler 2 and the inverter 7 which are a major part of the electric vehicle driving device 1 with the cover 16b removed. In the electric vehicle driving device 1 according to the third embodiment, a cooling water pump 30 is provided at the cooling surface 12a of the water-cooled plate 12.

The inverter 7 has the water-cooled plate 12 inside which the first cooling water path 13a and the second cooling water path 13b are formed, and the cooling water pump 30 which circulates the cooling water through the water path. The cooling water pump 30 is provided in contact with the water-cooled plate 12. In the present embodiment, the cooling water pump 30 is provided in contact with the cooling surface 12a of the water-cooled plate 12 and on the one side in the X direction of the case 16a and the cover 16b covering the electric component 15. The cooling water pump 30 is connected to the cooling-water-path connection portion 14a side of the first cooling water path 13a. The inverter 7 supplies power to the cooling water pump 30 and performs drive control of the cooling water pump 30.

With this configuration, since the cooling water pump 30 and the inverter 7 have an integrated structure, wiring connecting the cooling water pump 30 and the inverter 7 can be shortened, and wire connection of the wiring and the like can be simplified, whereby the weight and the size of the electric vehicle driving device 1 can be reduced.

In the present embodiment, the oil cooler 2 is provided in contact with the cooling surface 12a, and the oil cooler 2 and the electric component 15 are arranged side by side with each other. Since the inverter 7, the oil cooler 2, and the cooling water pump 30 are formed in an integrated structure (3 in 1), workability in attachment of the electric vehicle driving device 1 to the electric vehicle can be improved. In addition, since the inverter 7, the oil cooler 2, and the cooling water pump 30 are integrated, the strengths and vibration resistances of the inverter 7, the oil cooler 2, and the cooling water pump 30 can be improved.

### Fourth Embodiment

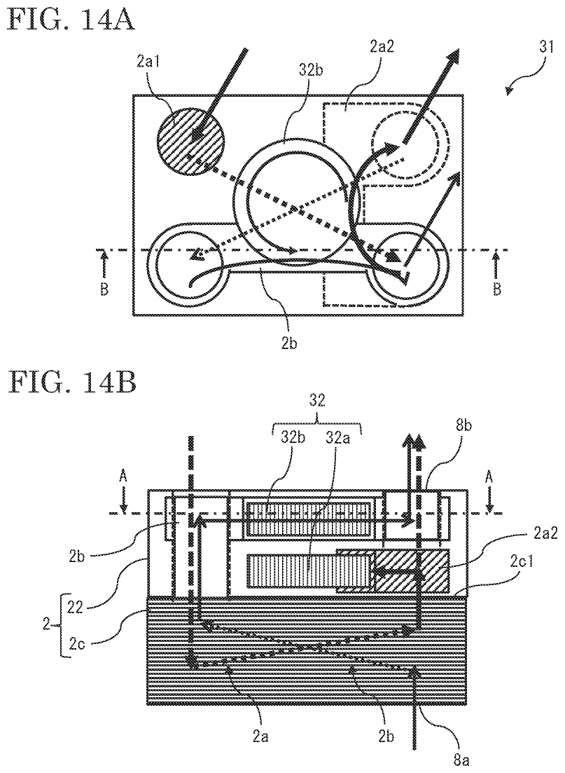

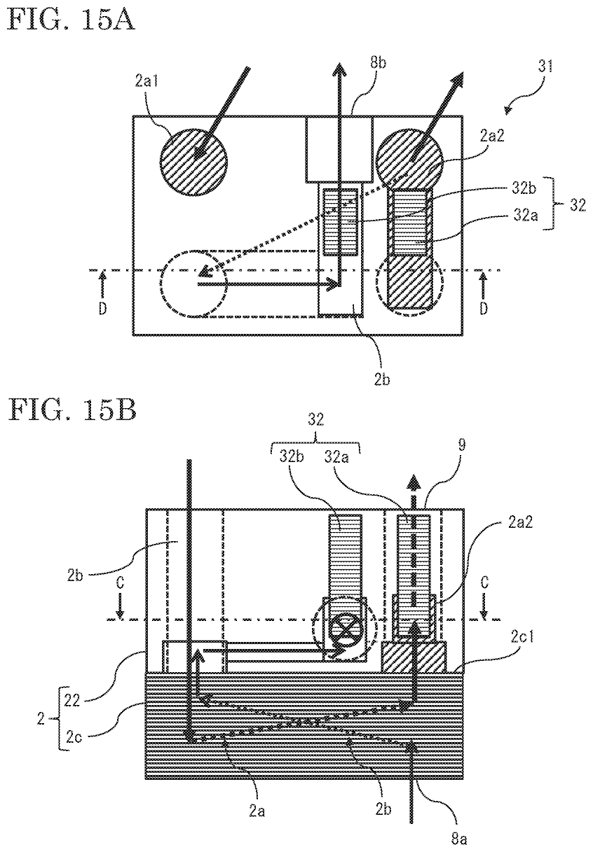

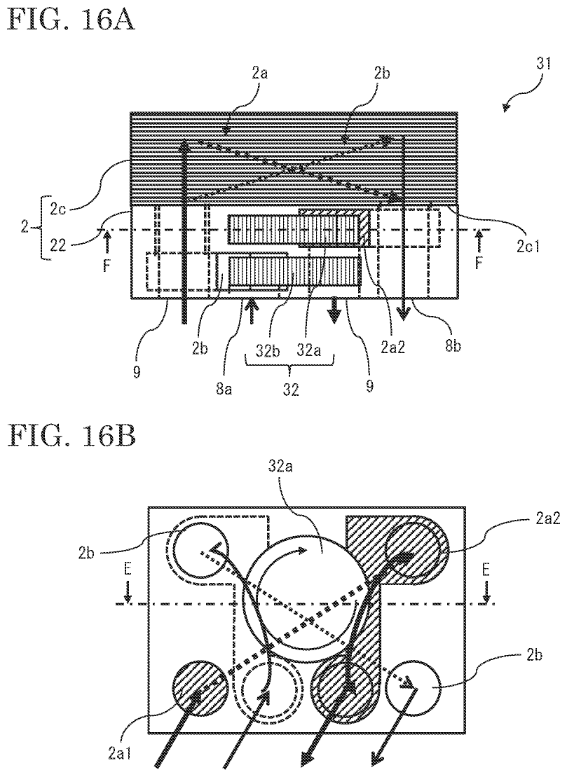

An electric vehicle driving device 1 according to the fourth embodiment of the present disclosure will be described. FIG. 14A is a sectional view showing the oil cooler 2 which is a major part of the electric vehicle driving device 1 according to the fourth embodiment when cut at an A-A cross-section position in FIG. 14B. FIG. 14B is a sectional view of the oil cooler 2 when cut at a B-B cross-section position in FIG. 14A. FIG. 15A is a sectional view showing the oil cooler 2 which is a major part of another electric vehicle driving device 1 according to the fourth embodiment when cut at a C-C cross-section position in FIG. 15B. FIG. 15B is a sectional view of the oil cooler 2 when cut at a D-D cross-section position in FIG. 15A. FIG. 16A is a sectional view showing the oil cooler 2 which is a major part of another electric vehicle driving device 1 according to the fourth embodiment when cut at an E-E cross-section position in FIG. 16B. FIG. 16B is a sectional view of the oil cooler 2 when cut at an F-F cross-section position in FIG. 16A. In the electric vehicle driving device 1 according to the fourth embodiment, a motive power conversion mechanism 31 which produces oil flow in the oil cooler 2 by water flow is provided.

The oil cooler 2 has the oil-cooler water path 2a through which the cooling water flows, and the oil-cooler oil path 2b through which the oil flows, and the oil-cooler water path 2a and the oil-cooler oil path 2b are arranged separately from each other without communicating with each other. At the oil cooler 2, the motive power conversion mechanism 31 which produces oil flow in the oil-cooler oil path 2b using, as motive power, water flow of the cooling water flowing through the oil-cooler water path 2a, is provided.

The configuration of the motive power conversion mechanism 31 of the present embodiment will be described with reference to FIG. 14A and FIG. 14B. The oil cooler 2 has the end plate 22 which is a part of the oil cooler 2. A part of the oil cooler 2 other than the end plate 22 is a body portion 2c of the oil cooler 2. The end plate 22 has the oil-cooler water path 2a and the oil-cooler oil path 2b arranged separately from each other without communicating with each other, and the motive power conversion mechanism 31 is provided at the end plate 22.

The motive power conversion mechanism 31 stores gears 32 formed of a pair of magnets or gears 32 one of which is formed of a magnet and another of which is formed of a magnetic material, in the oil-cooler water path 2a and the oil-cooler oil path 2b separated from each other, respectively. Via a magnetic force, rotation of the gear 32 on the oil-cooler water path 2a side is transmitted to the gear 32 on the oil-cooler oil path 2b side. The gear 32 on the oil-cooler water path 2a side is a gear 32a, and the gear 32 on the oil-cooler oil path 2b side is a gear 32b. As rotation of the gear 32a is transmitted to the gear 32b, the gear 32b rotates. The gears 32 may be any components as long as a rotational force can be transmitted from the gear 32a to the gear 32b, and therefore the entirety or a part of the gears 32 may be formed of magnets or magnetic materials.

In FIG. 14A and FIG. 14B, the directions in which the cooling water flows are indicated by arrows drawn by thick lines, and the directions in which the oil flows are indicated by arrows drawn by thin lines. The arrows drawn by thick lines and the arrows drawn by thin lines are different in arrow end shape. A route through which the cooling water flows will be described. The cooling water is supplied from the external-water-cooled system to the first cooling water path 13a, and the cooling water having passed through the first cooling water path 13a flows through the oil-cooler-water-path connection portion 9 into an oil-cooler water path 2a1 in the end plate 22 shown at the left in FIG. 14A. After passing through the oil-cooler water path 2a in the body portion 2c of the oil cooler 2, the cooling water flows into an oil-cooler water path 2a2 in the end plate 22, passes through the oil-cooler water path 2a2 indicated by a broken line at the right in FIG. 14A, and then flows through the oil-cooler-water-path connection portion 9 into the second cooling water path 13b. As shown in FIG. 14B, the gear 32a is provided in the end plate 22 so as to be partially exposed to the oil-cooler water path 2a2. As the cooling water flows through the oil-cooler water path 2a2, the gear 32a rotates.

A route through which the oil flows will be described. The oil flows into the oil-cooler oil path 2b in the body portion 2c of the oil cooler 2 from the first oil-cooler-oil-path connection portion 8a shown at the lower right in FIG. 14B. After passing through the oil-cooler oil path 2b in the body portion 2c, the oil flows into the oil-cooler oil path 2b in the end plate 22 and then is discharged through the second oil-cooler-oil-path connection portion 8b. As shown in FIG. 14A, the gear 32b is provided in the end plate 22 so as to be partially exposed to the oil-cooler oil path 2b.

With this configuration, since the gear 32b rotates with rotation of the gear 32a, the oil present in the oil-cooler oil path 2b can be sucked from the body portion 2c side of the oil cooler 2, and the oil can be discharged through the second oil-cooler-oil-path connection portion 8b. With this oil flow, the low-temperature oil having undergone heat exchange between the cooling water and the oil is discharged through the second oil-cooler-oil-path connection portion 8b, whereby the low-temperature oil can be supplied to the heat generation portion of the electric vehicle driving device 1. In the heat generation portion to which the low-temperature oil is supplied, the heat generation portion can be cooled directly or indirectly through heat absorption by the oil. In addition, with the flow of the cooling water supplied from the external-water-cooled system, the oil for cooling the heat generation portion of the electric vehicle driving device 1 can be circulated, so that an oil pump for circulating the oil is not needed and thus the weight and the size of the electric vehicle driving device 1 can be reduced. In addition, since oil flow is produced by water flow, power consumption can be reduced.

The end plate 22 storing the gears 32 may be provided at any of surfaces of the oil cooler 2. The rotary bodies provided to the motive power conversion mechanism 31 are not limited to gears. For example, a configuration in which a plurality of impellers are provided to a rotary shaft may be adopted. If the rotary bodies provided to the motive power conversion mechanism 31 are the gears 32, the size and the cost of the motive power conversion mechanism 31 can be reduced.

It is desirable that the end plate 22 is made of a material through which a magnetic force readily passes, and the end plate 22 is formed of a resin material, for example. It is desirable that the magnet or the magnetic material forming the gear 32 is not rusted even in the oil-cooler water path 2a2. The magnet or the magnetic material that is not rusted is ferrite, alnico, iron-chromium-cobalt, samarium-cobalt, or samarium-iron-nitrogen, for example. In a case where a material subject to rust, such as iron, is used as the magnetic material, it is desirable that coating such as painting (organic coating) or plating (inorganic coating) treatment is performed on the material.

In the present disclosure, the motive power conversion mechanism 31 uses a magnetic force, and therefore, unlike a motive power conversion mechanism in which gears are connected via a shaft, the oil-cooler water path 2a and the oil-cooler oil path 2b are arranged separately from each other without communicating with each other. Thus, there is no such concern that the cooling water leaks from the oil-cooler water path 2a to the oil-cooler oil path 2b through an area around the shaft connecting the gears. Since the cooling water does not leak from the oil-cooler water path 2a to the oil-cooler oil path 2b, failure of the electric vehicle driving device 1 due to entry of the cooling water into the oil-cooler oil path 2b can be prevented. In addition, since the inverter, the oil cooler 2 having an oil pump function, and the cooling water pump are formed in an integrated structure, work for mounting these into the electric vehicle driving device 1 can be easily performed.

### <Modification 1>

With reference to FIG. 15A and FIG. 15B, a configuration in modification 1 will be described. In the configuration shown in FIG. 15B, the direction in which the gears 32 are provided is different as compared to the configuration shown in FIG. 14B. In the configuration shown in FIG. 14B, the gears 32 are provided in parallel to a side surface 2c1 of the body portion 2c of the oil cooler 2. In the configuration shown in FIG. 15B, the gears 32 are provided perpendicularly to the side surface 2c1 of the body portion 2c of the oil cooler 2. In addition, between the configurations in FIG. 14 and FIG. 15, the direction in which the oil is discharged through the second oil-cooler-oil-path connection portion 8b is different. In the configuration shown in FIG. 14B, the oil is discharged in the direction perpendicular to the side surface 2c1 of the body portion 2c of the oil cooler 2. In the configuration shown in FIG. 15B, the oil is discharged in the direction parallel to the side surface 2c1 of the body portion 2c of the oil cooler 2. In the configuration shown in FIG. 14B, the size of the end plate 22 can be reduced as compared to the configuration shown in FIG. 15B.

### <Modification 2>

With reference to FIG. 16A and FIG. 16B, a configuration in modification 2 will be described. In the configuration shown in FIG. 16A, the position in which the first oil-cooler-oil-path connection portion 8a is provided is different from the configuration shown in FIG. 14A. In the configuration shown in FIG. 14A, the first oil-cooler-oil-path connection portion 8a is provided at the body portion 2c of the oil cooler 2. In the configuration shown in FIG. 16A, the first oil-cooler-oil-path connection portion 8a is provided at the end plate 22. With this configuration, both of the first oil-cooler-oil-path connection portion 8a and the second oil-cooler-oil-path connection portion 8b can be provided on the same side of the end plate 22. Since both of the first oil-cooler-oil-path connection portion 8a and the second oil-cooler-oil-path connection portion 8b are provided on the same side of the end plate 22, productivity of the electric vehicle driving device 1 can be improved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

Hereinafter, modes of the present disclosure are summarized as additional notes.

### (Additional Note 1)

An electric vehicle driving device comprising:
a motor;
a gear box storing a speed reduction mechanism connected to the motor, and a differential mechanism connected to the speed reduction mechanism;
an inverter which is electrically connected to the motor and converts power; and
an oil cooler which oil-cools the motor, wherein
the inverter has a first cooling water path and a second cooling water path through which cooling water flows,
the oil cooler has an oil-cooler water path through which the cooling water flows,
the oil cooler is provided in contact with the inverter,
at the contact part, the first cooling water path and the oil-cooler water path are connected, and the second cooling water path and the oil-cooler water path are connected, and
a water path is formed such that the cooling water flows in order of the first cooling water path, the oil-cooler water path, and then the second cooling water path.

### (Additional Note 2)

The electric vehicle driving device according to additional note 1, wherein
the oil cooler has an oil-cooler oil path through which oil flows,
the motor and the gear box have an oil path connected to the oil-cooler oil path,
the oil cooler is provided in contact with the motor or the gear box on a side opposite to the inverter,
at the contact part, the oil path and the oil-cooler oil path are connected, and
the oil cooler is located so as to be interposed between the inverter and the motor or the gear box.

### (Additional Note 3)

The electric vehicle driving device according to additional note 1, wherein
the inverter has an electric component, and a water-cooled plate inside which the first cooling water path and the second cooling water path are formed,
the water-cooled plate has a cooling surface on which the electric component is mounted, and
the oil cooler is provided in contact with the cooling surface and arranged side by side with the electric component.

### (Additional Note 4)

The electric vehicle driving device according to any one of additional notes 1 to 3, wherein
the inverter has a power module and a capacitor arranged adjacently to the first cooling water path, and a cooling water entrance through which the cooling water flows into the first cooling water path, and
the first cooling water path is provided such that the cooling water flowing inward through the cooling water entrance passes in order of the power module and then the capacitor through a part of the first cooling water path to which the power module and the capacitor are arranged adjacently.

### (Additional Note 5)

The electric vehicle driving device according to any one of additional notes 1 to 4, wherein
the inverter has a water-cooled plate inside which the first cooling water path and the second cooling water path are formed, and a cooling water pump which circulates the cooling water through the water path, and
the cooling water pump is provided in contact with the water-cooled plate.

### (Additional Note 6)

The electric vehicle driving device according to any one of additional notes 1 to 5, wherein
the oil cooler has an oil-cooler oil path through which oil flows,
the oil-cooler water path and the oil-cooler oil path are arranged separately from each other without communicating with each other, and
a motive power conversion mechanism which produces oil flow in the oil-cooler oil path using, as motive power, water flow of the cooling water flowing through the oil-cooler water path, is provided.

### (Additional Note 7)

The electric vehicle driving device according to additional note 6, wherein
the motive power conversion mechanism stores gears formed of a pair of magnets or gears one of which is formed of a magnet and another of which is formed of a magnetic material, in the oil-cooler water path and the oil-cooler oil path separated from each other, respectively, and
via a magnetic force, rotation of the gear on the oil-cooler water path side is transmitted to the gear on the oil-cooler oil path side.

### (Additional Note 8)

The electric vehicle driving device according to additional note 2, wherein
the first cooling water path and the oil-cooler water path, the second cooling water path and the oil-cooler water path, and the oil path and the oil-cooler oil path, are connected by one-touch connector structures.

### DESCRIPTION OF THE REFERENCE CHARACTERS

1 electric vehicle driving device
2 oil cooler
2a, 2a1, 2a2 oil-cooler water path
2b oil-cooler oil path
2c body portion
2c1 side surface
3 motor
3a rotary shaft
3b rotor
3c housing
3d stator
4 speed reduction mechanism
5 differential mechanism
6 gear box
6a drive shaft
7 inverter
8 oil-cooler-oil-path connection portion
8a first oil-cooler-oil-path connection portion
8b second oil-cooler-oil-path connection portion
9 oil-cooler-water-path connection portion
10 oil path
10a, 10b plate oil path
11, 11a, 11b oil path connection portion
12 water-cooled plate
12a cooling surface
13a first cooling water path
13b second cooling water path
13b1 second cooling-water-path connection portion
14a, 14b cooling-water-path connection portion
15 electric component
16a case
16b cover
17 cooling water entrance
18 cooling water exit
19 oil header
20 cooling water header
21 protruding portion
22, 22a, 22b end plate
22a1 end plate water path
22b1 end plate oil path
23 nipple
24 O ring
25 power module
26 capacitor
27a, 27b first plate-oil-path connection portion
28a, 28b second plate-oil-path connection portion
29 opening
30 cooling water pump
31 motive power conversion mechanism
32, 32a, 32b gear

What is claimed is:

1. An electric vehicle driving device comprising:
a motor;
a gear box storing a speed reduction mechanism connected to the motor, and a differential mechanism connected to the speed reduction mechanism;
an inverter which is electrically connected to the motor and converts power; and
an oil cooler which oil-cools the motor, wherein
the inverter has a first cooling water path and a second cooling water path through which cooling water flows,
the oil cooler has an oil-cooler water path through which the cooling water flows,
the oil cooler is provided in contact with the inverter,
at the contact part, the first cooling water path and the oil-cooler water path are connected, and the second cooling water path and the oil-cooler water path are connected, and
a water path is formed such that the cooling water flows in order of the first cooling water path, the oil-cooler water path, and then the second cooling water path.

2. The electric vehicle driving device according to claim 1, wherein
the oil cooler has an oil-cooler oil path through which oil flows,
the motor and the gear box have an oil path connected to the oil-cooler oil path,
the oil cooler is provided in contact with the motor or the gear box on a side opposite to the inverter,
at the contact part, the oil path and the oil-cooler oil path are connected, and
the oil cooler is located so as to be interposed between the inverter and the motor or the gear box.

3. The electric vehicle driving device according to claim 1, wherein
the inverter has an electric component, and a water-cooled plate inside which the first cooling water path and the second cooling water path are formed,
the water-cooled plate has a cooling surface on which the electric component is mounted, and
the oil cooler is provided in contact with the cooling surface and arranged side by side with the electric component.

4. The electric vehicle driving device according to claim 1, wherein
the inverter has a power module and a capacitor arranged adjacently to the first cooling water path, and a cooling water entrance through which the cooling water flows into the first cooling water path, and
the first cooling water path is provided such that the cooling water flowing inward through the cooling water entrance passes in order of the power module and then the capacitor through a part of the first cooling water path to which the power module and the capacitor are arranged adjacently.

5. The electric vehicle driving device according to claim 1, wherein
the inverter has a water-cooled plate inside which the first cooling water path and the second cooling water path are formed, and a cooling water pump which circulates the cooling water through the water path, and
the cooling water pump is provided in contact with the water-cooled plate.

6. The electric vehicle driving device according to claim 1, wherein
the oil cooler has an oil-cooler oil path through which oil flows,
the oil-cooler water path and the oil-cooler oil path are arranged separately from each other without communicating with each other, and
a motive power conversion mechanism which produces oil flow in the oil-cooler oil path using, as motive power, water flow of the cooling water flowing through the oil-cooler water path, is provided.

7. The electric vehicle driving device according to claim 6, wherein
the motive power conversion mechanism stores gears formed of a pair of magnets or gears one of which is formed of a magnet and another of which is formed of a magnetic material, in the oil-cooler water path and the oil-cooler oil path separated from each other, respectively, and
via a magnetic force, rotation of the gear on the oil-cooler water path side is transmitted to the gear on the oil-cooler oil path side.

8. The electric vehicle driving device according to claim 2, wherein
the first cooling water path and the oil-cooler water path, the second cooling water path and the oil-cooler water path, and the oil path and the oil-cooler oil path, are connected by one-touch connector structures.
